(19) United States
(12) Patent Application Publication
(10) Pub. No.: US 2011/0012151 A1
(43) Pub. Date: Jan. 20, 2011

(54) LIGHT EMITTING DEVICE

(75) Inventor: Reiji Ono, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/706,929

(22) Filed: Feb. 17, 2010

(30) Foreign Application Priority Data
Jul. 16, 2009 (JP) 2009-167434

(51) Int. Cl. H01L 33/48; H01L 33/44; H01L 33/62

(52) U.S. Cl. 257/98; 257/99; 257/E33.056; 257/E33.061; 257/E33.066

(57) ABSTRACT

A light emitting device includes: a mounting member including a recess; a light emitting element provided in the recess and made of a semiconductor; an electrostatic discharge protection element provided in the recess and connected parallel to the light emitting element; and a translucent resin layer mixed with a filler capable of reflecting emitted light from the light emitting element, covering the electrostatic discharge protection element and not covering the light emitting element.

### CROSS-REFERENCE TO RELATED APPLICATIONS

This application is based upon and claims the benefit of priority from the prior Japanese Patent Application No. 2009-167434, filed on Jul. 16, 2009; the entire contents of which are incorporated herein by reference.

### BACKGROUND

An SMD (surface-mounted device) type white LED (light emitting device) includes, for instance, an LED chip, a lead frame to which the LED chip is bonded, a molded body having a recess in which the LED chip is housed, and a resin mixed with phosphors and filled in the recess of the molded body.

The LED chip, which is made of a compound semiconductor multilayer body, is more susceptible to breakdown due to ESD (electrostatic discharge) than Si elements. Parallel connection of an LED and a Zener diode in mutually reverse polarity can protect the LED against large ESD, if any, externally applied thereto.

However, the Zener diode provided to increase the ESD withstand capability increases in size, which results in blocking and absorbing the emitted light from the LED. This may decrease the light extraction efficiency.

JP-A 2008-085113 (Kokai) discloses a light emitting device, which prevents the decrease of light extraction efficiency while reducing its profile. In this example, the Zener diode is provided at a lower position than the LED to prevent the decrease of light extraction efficiency.

### SUMMARY

According to an aspect of the invention, there is provided a light emitting device including: a mounting member including a recess; a light emitting element provided in the recess and made of a semiconductor; an electrostatic discharge protection element provided in the recess and connected parallel to the light emitting element; and a translucent resin layer mixed with a filler capable of reflecting emitted light from the light emitting element, covering the electrostatic discharge protection element and not covering the light emitting element.

According to another aspect of the invention, there is provided a light emitting device including: a mounting member including a recess; a light emitting element provided in the recess and made of a semiconductor; an electrostatic discharge protection element provided in the recess and connected parallel to the light emitting element; and a translucent resin layer mixed with a filler capable of reflecting emitted light from the light emitting element, covering the electrostatic discharge protection element and not covering the light emitting element, the recess including a first bottom surface and a second bottom surface, the first bottom surface being bonded to the light emitting element, and the second bottom surface being provided below the first bottom surface bonded to the electrostatic discharge protection element.

According to still another aspect of the invention, there is provided a light emitting device including: a mounting member including a recess; a light emitting element provided in the recess and made of a semiconductor; an electrostatic discharge protection element provided in the recess and connected parallel to the light emitting element; and a translucent resin layer mixed with a filler capable of reflecting emitted light from the light emitting element, covering the electrostatic discharge protection element and not covering the light emitting element, the recess including a first bottom surface and a second bottom surface, the first bottom surface being bonded to the light emitting element, and the second bottom surface being provided above the first bottom surface bonded to the electrostatic discharge protection element.

### BRIEF DESCRIPTION OF THE DRAWINGS

FIGS. 1A to 1D are schematic perspective views of a light emitting device according to a first embodiment;

FIGS. 2A to 2C are schematic views of the light emitting device according to the first embodiment;

FIGS. 3A and 3B are schematic views of a light emitting device according to a comparative example;

FIG. 4 is a graph of reflectance of metal;

FIGS. 5A and 5B are schematic views of a light emitting device according to a second embodiment; and

FIGS. 6A and 6B are schematic views of a light emitting device according to a third embodiment.

### DETAILED DESCRIPTION OF THE INVENTION

Embodiments of the invention will now be described with reference to the drawings.

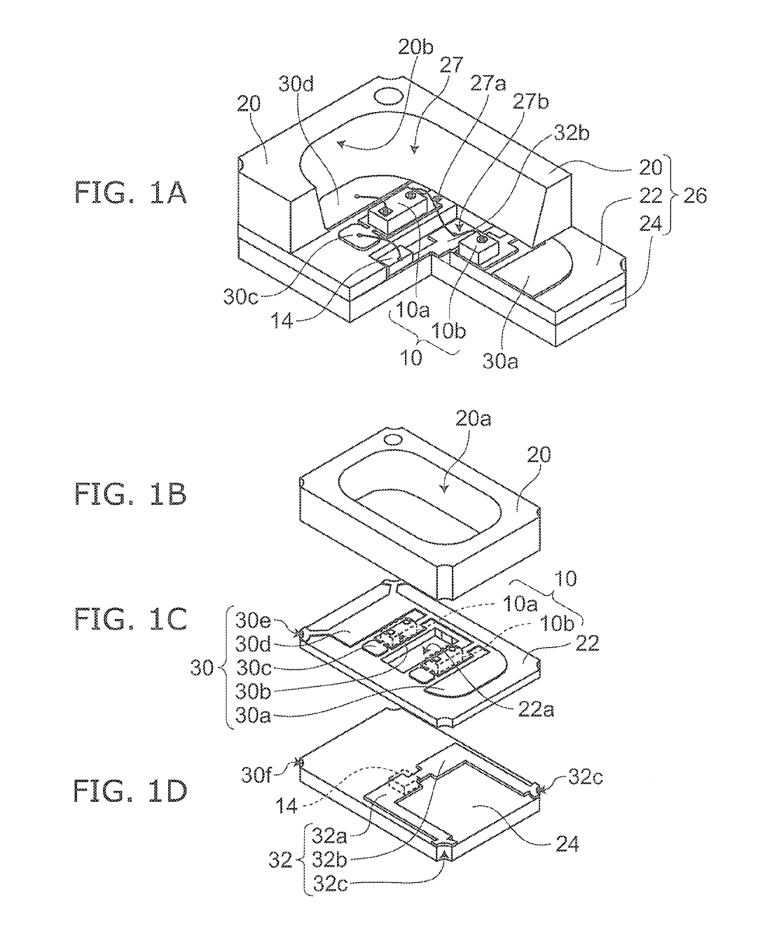

FIG. 1A is a partially cutaway schematic perspective view of a light emitting device according to a first embodiment of the invention, and FIGS. 1B, 1C, and 1D are schematic perspective views of first, second, and third ceramic layers constituting its mounting member, respectively. It is noted that FIG. 1A shows the state before the recess provided in the mounting member is filled with resin.

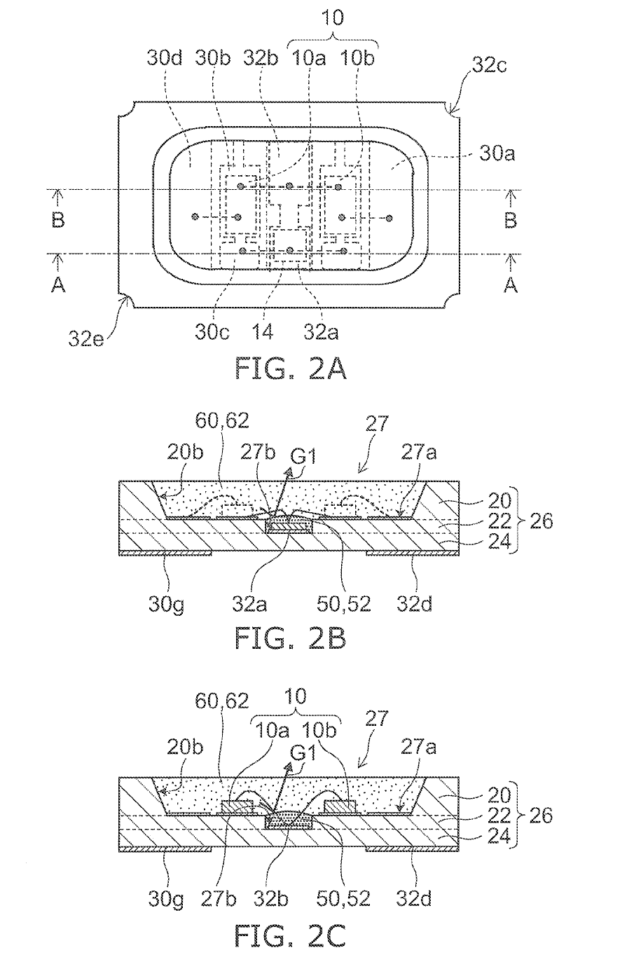

FIG. 2A is a schematic plan view of the light emitting device according to the first embodiment shown in FIGS. 1A to 1D, FIG. 2B is a schematic cross-sectional view taken along line A-A, and FIG. 2C is a schematic cross-sectional view taken along line B-B.

The light emitting device includes a mounting member 26, light emitting elements 10a and 10b provided in its recess 27, an electrostatic discharge protection element 14 provided in the recess 27 and connected parallel to the light emitting element 10 in mutually reverse polarity, a translucent resin layer 50 mixed with a reflective filler 52 and provided so as to cover the electrostatic discharge protection element 14 and not to cover the light emitting element 10, phosphor particles 62 capable of absorbing the emitted light from the light emitting element 10 and emitting wavelength-converted light, and a sealing resin layer 60 dispersed with the phosphor particles 62 and filled in the recess 27 so as to cover the light emitting element 10 and the translucent resin layer 50. The light emitting elements 10a and 10b are bonded to a first bottom surface 27a of the recess 27. The electrostatic discharge protection element 14 is bonded to a second bottom surface 27b of the recess 27.

The reflective filler 52 is illustratively particulate. The filler 52 can be made of such materials as titanates including potassium titanate (K₂TiO₃), titanium oxides (TiOₓ) including titanium dioxide (TiO₂), Al₂O₃, AlN, and combinations of Al and SiO₂. By using K₂TiO₃, TiOₓ and the like, high reflectance can be maintained in a wide wavelength range from ultraviolet to visible light.

The mounting member 26 of this embodiment is made of a fired body of a ceramic such as alumina. The fired ceramic body has a stacked structure of a first ceramic layer 20 having a through hole 20a as shown in FIG. 1B, a second ceramic layer 22 to which the light emitting elements 10a and 10b are bonded as shown in FIG. 1C, and a third ceramic layer 24 serving as a substrate to which the electrostatic discharge protection element 14 is bonded as shown in FIG. 1D.

A second conductive portion 32 illustratively made of a metallized thick film is provided on the upper surface and side surface of the third ceramic layer 24, and the electrostatic discharge protection element 14 such as a Zener diode is bonded thereto. The second conductive portion 32 is connected through a side surface portion 32c provided at a corner of the third ceramic layer 24 to a conductive portion 32d further provided on the lower surface of the third ceramic layer 24.

The second ceramic layer 22 has a through hole 22a, and a first conductive portion 30 is provided on its upper surface and side surface. The first conductive portion 30 includes a bonding region 30b for bonding the two chips of the light emitting elements 10a and 10b, and wire bonding regions 30a and 30d. The first conductive portion 30 is connected to the lower-surface conductive portion 30g of the third ceramic layer 24 through a side surface portion 30e and through a side surface portion 30f provided at a corner of the third ceramic layer 24.

The first ceramic layer 20 stacked on the second ceramic layer 22 has a through hole 20a. The sidewall 20b of the through hole 20a is preferably beveled because the ceramic layer illustratively made of alumina has high reflectance and can reflect light upward, thereby increasing the light extraction efficiency.

The light emitting element 10 made of an InGaAlN-based material can emit light in a wavelength range from ultraviolet through blue to green. In the case where the light emitting element 10 is formed on a substrate illustratively made of sapphire, the sapphire substrate side of the light emitting element 10 is bonded onto the bonding region 30b, and the cathode electrode of the light emitting element 10 can be connected to the wire bonding region 30d of the first conductive portion 30 by a bonding wire. Furthermore, the anode electrode of the light emitting element 10 can be connected to the wire bonding region 32b of the second conductive portion 32 by a bonding wire.

In this specification, “InGaAlN” refers to a material represented by the composition formula BₓIn_{y}Ga_{z}Al_{1-x-y-z}N (where 0≦x≦1, 0≦y≦1, 0≦z≦1, x+y+z≦1), including those doped with p-type or n-type impurity.

In the case where the light emitting element 10 is made of an InGaAlP-based material, it can emit visible light in a wavelength range from green to red. If the visible light is directly used as emitted light, the phosphor particles may be omitted.

In this specification, “InGaAlP” refers to a material represented by the composition formula Inₓ(Ga_{y}Al_{1-y})₁₋ₓP (where 0≦x≦1, 0≦y≦1), including those doped with p-type or n-type impurity.

In the figures, the light emitting element 10 is composed of two chips connected in parallel. If the optical output increases in proportion to the chip size, one chip having a large size can be used. However, in the structure in which a semiconductor multilayer body is provided on the sapphire substrate with one current path being generally parallel to the chip surface, it is difficult to obtain an optical output in proportion to the chip size. Thus, a plurality of chips operated in parallel can increase the optical output more easily while suppressing the decrease in efficiency. In this case, the chip size can illustratively be 250 μm×500 μm.

The electrostatic discharge protection element 14 serves to protect the light emitting element 10 against high current or high voltage due to ESD and the like. For instance, in the case where the electrostatic discharge protection element 14 is a Zener diode, it is connected parallel to the light emitting element 10 with reverse polarity. More specifically, the anode electrode of the Zener diode 14 is connected to the wire bonding region 30c of the first conductive portion 30 by a bonding wire, and the cathode electrode is connected to the bonding region 32a of the second conductive portion 32 illustratively by a conductive adhesive or solder material. Here, the polarity of the light emitting element 10 and the polarity of the electrostatic discharge protection element 14 may be both inverted.

In this configuration, even if a reverse surge voltage exceeding the maximum rated DC reverse voltage is applied to the light emitting element 10, it is bypassed through the Zener diode 14, and hence the light emitting element 10 can be protected. Furthermore, even if a forward surge current exceeding the maximum rated forward current flow through the light emitting element 10 due to a forward surge voltage, it is bypassed through the Zener diode 14, and hence the light emitting element 10 can be readily protected.

In order to protect the light emitting element 10, it is preferable that the pn junction area of the Zener diode 14 is not too small. For two parallel light emitting elements 10a and 10b measuring 250 μm×500 μm, a Zener diode measuring 400 μm×400 μm, for instance, can readily maintain the surge withstand capability at the required level.

In the through hole 22a provided in the second ceramic layer 22 and constituting the recess 27 of the mounting member 26, the Zener diode 14 is covered with a translucent resin 50 mixed with a reflective filler 52 and illustratively made of silicone. Hence, part G1 of the emitted light from the light emitting element 10 is reflected upward near the surface of the translucent resin layer 50. If the upper surface of the Zener diode 14 is located below the first bottom surface 27a of the recess 27, reflection can be further enhanced. Furthermore, if the upper surface of the translucent resin layer 50 is raised upward above the first bottom surface 27a of the recess 27 as shown in FIG. 1B, reflection can be enhanced more easily.

The through hole 20a of the first ceramic layer 20 also constitutes the recess 27 of the mounting member 26. A translucent resin mixed with phosphor particles 62, for instance, is filled in the recess 27 so as to cover the translucent resin layer 50 filled in the through hole 22a and the light emitting element 10, and constitutes a sealing resin layer 60. Here, it is preferable to apply the sealing resin layer 60 after semi-curing or curing the translucent resin layer 50.

The phosphor particle 62 absorbs the emitted light from the light emitting element 10 and emits wavelength-converted light. If the light emitting element 10 emits blue-violet light at a wavelength of 450 nm and the phosphor particle 62 is illustratively made of silicates capable of emitting yellow light around a wavelength of 560 nm, then white or incandescent light can be obtained as a mixed color thereof. It is preferable that the sidewall 20b be suitably beveled because the light extraction efficiency can then be increased. Furthermore, the wavelength-converted light is also reflected near the surface of the translucent resin layer 50 mixed with the filler 52, and hence the light extraction efficiency can be increased. In the case where the emitted light is in a wavelength range from ultraviolet to blue-violet, the phosphor particle 62 may be made of a material containing YAG (yttrium aluminum garnet).

The lower-surface conductive portion 30g and the side-surface conductive portion 30f constitute the first conductive portion 30. Furthermore, the lower-surface conductive portion 32d constitutes the second conductive portion 32. The conductive portions 30g and 32d thus provided facilitate electrical connection to a circuit board and the like.

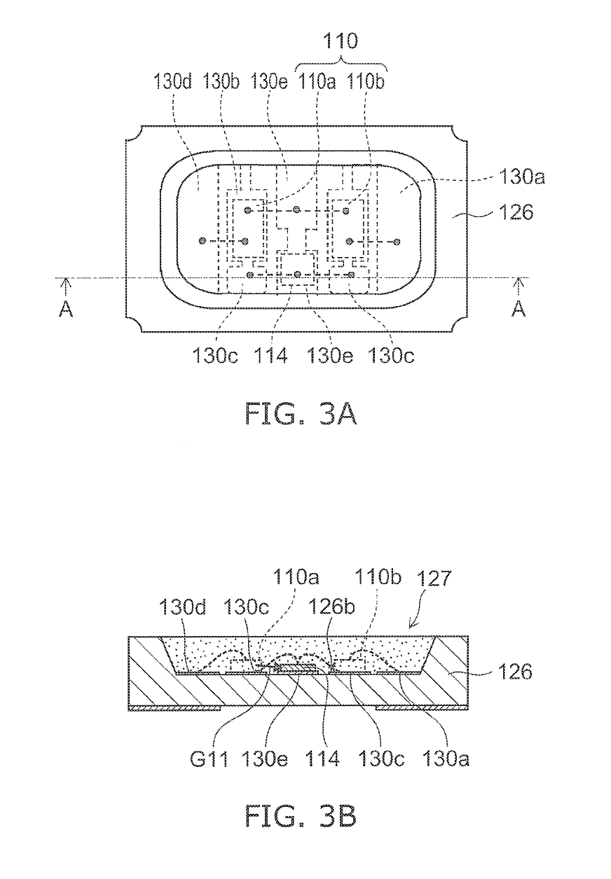

FIG. 3A is a schematic plan view of a light emitting device according to a comparative example, and FIG. 3B is a schematic cross-sectional view thereof taken along line A-A.

Each of light emitting elements 110a and 110b measures 250 μm×500 μm, for instance, and is bonded with a metal solder or the like to a conductive portion 130b provided on a mounting member 126 illustratively made of a ceramic. A Zener diode 114 measures 400 μm×400 μm, for instance, and is bonded with a metal solder or the like to a conductive portion 130e. Conductive portions 130a, 130c, 130d, and 130e serve as wire bonding regions.

The Zener diode 114 is often made of silicon. Because the bandgap wavelength of silicon is generally 1.11 μm, it absorbs visible light including blue and yellow lights. For instance, as shown in this figure, if the emitted light G11 from the light emitting element 110 is easily incident on the Zener diode 114 from its side surface and upper surface, optical absorption occurs therein and decreases the light extraction efficiency.

Use of Au for the electrode surface of the Zener diode 114 can facilitate wire bonding and increase reliability. However, the reflectance of Au decreases in the short wavelength range.

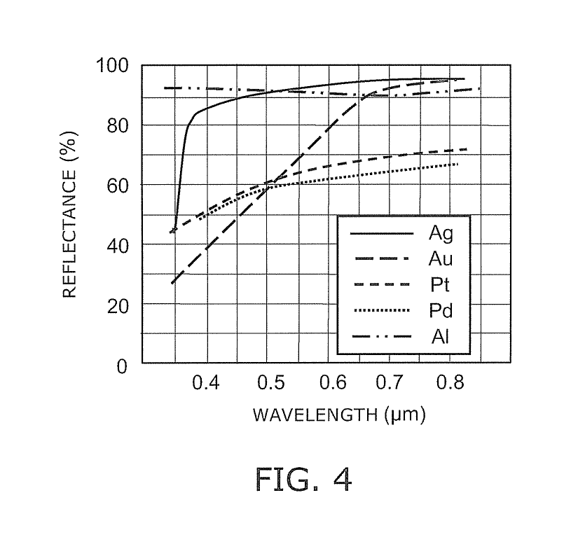

FIG. 4 is a graph showing an example of dependence of reflectance on the emitted light wavelength. The vertical axis represents reflectance (%), and the horizontal axis represents the wavelength of emitted light (μm).

The reflectance of Au is generally 50% at the blue-violet wavelength of 0.45 μm and generally 70% at the yellow wavelength of 0.56 μm, which are lower than the reflectance of Al and Ag. That is, the light incident from the light emitting element 110 on the Au electrode of the Zener diode 114 is not sufficiently reflected. This decreases the light extraction efficiency.

In contrast, in this embodiment, the emitted light from the light emitting element 10 is reflected by the filler covering the electrostatic discharge protection element 14. This can reduce optical absorption by the electrostatic discharge protection element 14 and increase the light extraction efficiency.

Furthermore, the chip of the Zener diode 14 bonded into the recess 27 of the mounting member 26 and wire-bonded to each electrode of the light emitting element 10 require space at least several times the size of the Zener diode 14 as shown in FIGS. 1A to 1D. In the conductive portion provided on the surface of the ceramic layer illustratively made of alumina, an Au plating film is often provided on the surface of the thick film to ensure chip bonding and wire bonding. However, Au has low reflectance as shown in FIG. 4. In this embodiment, as shown in FIG. 2C, the surface of the conductive portion 32 is covered with a translucent resin 50 mixed with a reflective filler 52. This can increase the reflectance and further improve the light extraction efficiency.

Furthermore, in this embodiment, the second bottom surface 27b to which the Zener diode 14 is bonded is located below the first bottom surface 27a to which the light emitting element 10 is bonded. This can facilitate filling the translucent resin 50 in the liquid state.

Instead of the Zener diode, the electrostatic discharge protection element can illustratively be a varistor (variable resistor). The varistor can be formed from a ceramic such as zinc oxide and strontium titanate with an additive added thereto, sandwiched between two electrodes. The varistor exhibits nonlinear resistance, and its electrical resistance sharply decreases with the increase of applied voltage. Thus, it can bypass static electricity and protect the light emitting element from surge. The surface of the varistor including the electrodes has low reflectance. Hence, if it is placed near the light emitting element, the light extraction efficiency decreases.

As described above, in the first embodiment, the translucent resin 50 mixed with the filler 52 capable of reflecting the emitted light from the light emitting element 10 can suppress the decrease of light extraction efficiency resulting from optical absorption by the electrostatic discharge protection element 14 and caused by the low-reflectance conductive portion for mounting it. Thus, the first embodiment provides a light emitting device with improved surge withstand capability and increased light extraction efficiency. In large displays and backlight sources for image displays, for instance, the light emitting devices are often used in external environments susceptible to surge, and the number of devices used is large. The light emitting device of this embodiment is useful in such applications.

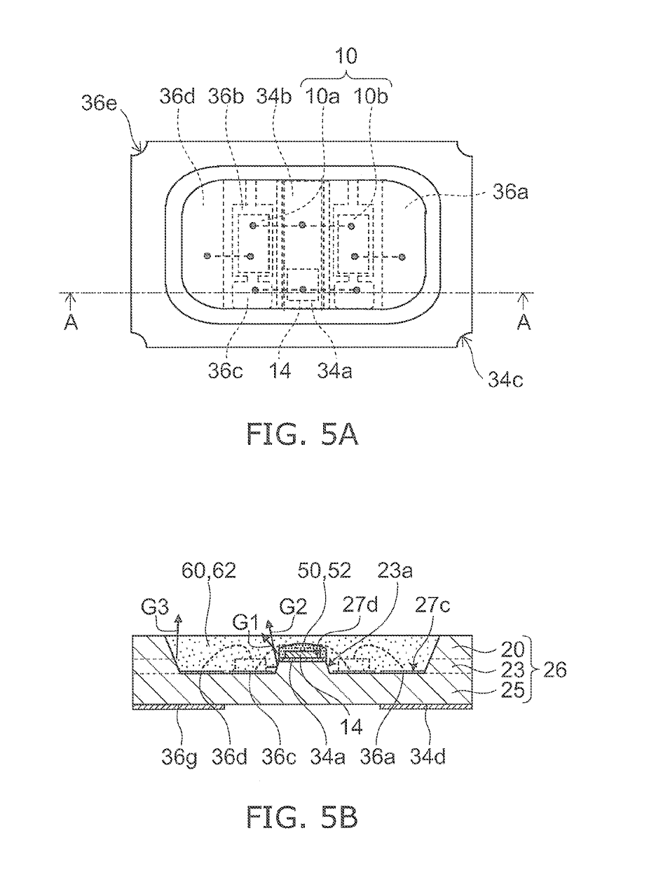

FIG. 5A is a schematic plan view of a light emitting device according to a second embodiment, and FIG. 5B is a schematic cross-sectional view thereof taken along line A-A.

The mounting member 26 includes a recess 27. The bottom surface of the recess 27 includes a first bottom surface 27c to which light emitting elements 10a and 10b are bonded and a second bottom surface 27d to which a Zener diode 14 is bonded. A first conductive portion 36 is provided on the third ceramic layer 25. The first conductive portion 36 includes a bonding region 36b to which the light emitting elements 10a and 10b are bonded, wire bonding regions 36a, 36c and 36d, and a side surface portion 36e. The surface of the third ceramic layer 25 including at least part of the bonding region 36b and the wire bonding regions 36a, 36c and 36d is exposed from the through hole provided in the second ceramic layer 23 and constitutes the first bottom surface 27c.

A second conductive portion 34 is provided on the second ceramic layer 23. The second conductive portion 34 includes a bonding region 34a to which the Zener diode 14 is bonded and a wire bonding region 34b. The surface of the second ceramic layer 23 including at least part of the bonding region 34a and the wire bonding region 34b constitutes the second bottom surface 27d. In this embodiment, the second bottom surface 27d is provided above the first bottom surface 27c.

A translucent resin layer 50 mixed with a reflective filler 52 is provided so as to cover the Zener diode 14 bonded to the bonding region 34a of the second conductive portion 34 on the second ceramic layer 23. The sidewall 23a of the second ceramic layer 23 can be beveled so that the emitted light G2 from the light emitting elements 10a and 10b can be reflected upward. If the second bottom surface 27d is located above the upper surface of the light emitting element 10, reflection can be further enhanced. Furthermore, the translucent resin layer 50 can reflect the emitted light G1 and wavelength-converted light, and the light extraction efficiency can be increased. Here, the light G3 directed from the light emitting elements 10a and 10b toward the sidewall of the recess 27 is reflected upward, and hence the light extraction efficiency can be increased.

If the wire bonding region 34b of the second conductive portion 34 provided on the second ceramic layer 23 is covered with the translucent resin layer 50 from above, the light extraction efficiency can be further increased.

The lower-surface conductive portion 36g constitutes the first conductive portion 36. Furthermore, the lower-surface conductive portion 34d constitutes the second conductive portion 34. This facilitates, electrical connection to a wiring board and the like.

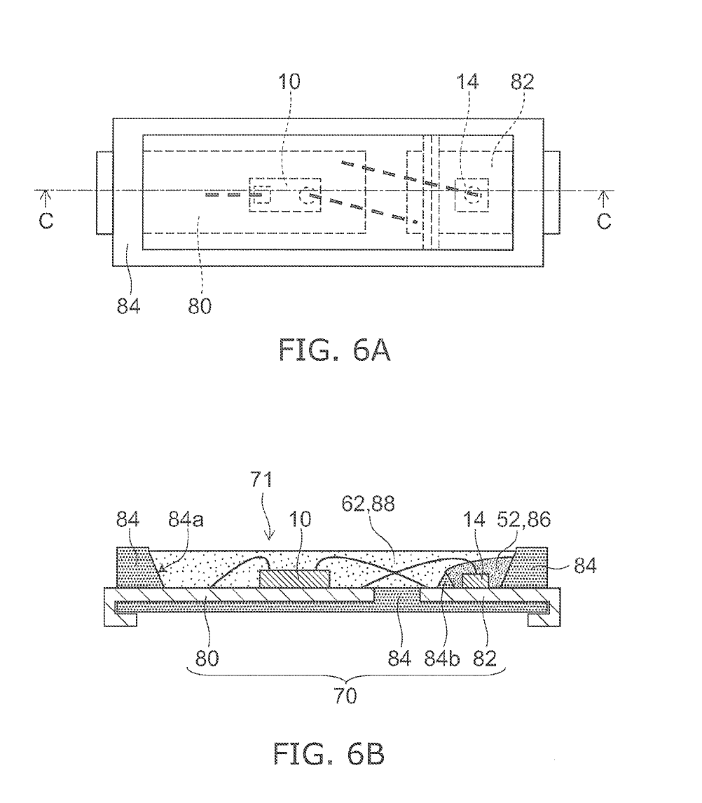

FIG. 6A is a schematic plan view of a light emitting device according to a third embodiment, and FIG. 6B is a schematic cross-sectional view thereof taken along line C-C.

The material of the mounting member is not limited to ceramics and the like. Leads 80 and 82 illustratively made of an iron-based or copper-based alloy can be combined with a resin molded body 84 to form a mounting member 70. A light emitting element 10 is bonded onto the first lead 80 using a conductive adhesive, metal eutectic solder or the like. An electrostatic discharge protection element 14 is bonded onto the second lead 82 using a conductive adhesive, metal eutectic solder or the like.

The first lead 80 and the second lead 82 are integrally molded in a thermoplastic resin, thermosetting resin or the like. Here, the thermoplastic resin or the thermosetting resin can be mixed with a reflective material such as K₂TiO₃ to form a molded body 84. Then, the emitted light from the light emitting element 10 is reflected upward by the sidewall 84a of the recess 71 of the molded body 84, and hence the light extraction efficiency can be increased.

The electrostatic discharge protection element 14 bonded to the second lead 82 is covered with a translucent resin layer 86 mixed with a reflective filler 52. Here, if the molded body 84 is provided with a protrusion 84b, the process for filling a liquid translucent resin 86 mixed with the filler 52 is facilitated. After the translucent resin 86 is semi-cured or cured illustratively by heating, a sealing resin 88 mixed with phosphor particles 62 is filled in the recess 71 and further cured.

Thus, even if the light emitting element 10 and the electrostatic discharge protection element 14 are bonded onto the bottom surfaces, which are generally coplanar in the recess 71, it is possible to reduce absorption of emitted light by the electrostatic discharge protection element 14 while reflecting the emitted light by the recess 71 of the mounting member 70. Consequently, the light extraction efficiency can be improved.

Furthermore, a Zener diode functioning as the electrostatic discharge protection element 14 can be connected antiparallel to the light emitting element 10 between the first lead 80 and the second lead 82. The light emitting device of this embodiment can be manufactured by the process for manufacturing a molded light emitting device, and hence high volume productivity can be achieved. This facilitates cost reduction.

The embodiments of the invention have been described with reference to the drawings. However, the invention is not limited to these embodiments. Those skilled in the art can variously modify the material, shape, size, layout and the like of the mounting member, light emitting element, electrostatic discharge protection element, translucent resin layer, sealing resin layer, filler, and phosphor particle constituting the embodiments, and such modifications are also encompassed within the scope of the invention as long as they do not depart from the spirit of the invention.

1. A light emitting device comprising:
a mounting member including a recess;
a light emitting element provided in the recess and made of a semiconductor;
an electrostatic discharge protection element provided in the recess and connected parallel to the light emitting element; and
a translucent resin layer mixed with a filler capable of reflecting emitted light from the light emitting element, covering the electrostatic discharge protection element and not covering the light emitting element.

2. The device according to claim 1, further comprising:
a sealing resin layer filled in the recess covering the light emitting element and the translucent resin layer, and being translucent.

3. The device according to claim 2, wherein the sealing resin layer is mixed with phosphor particles capable of absorbing the emitted light from the light emitting element and emitting wavelength-converted light.

4. The device according to claim 1, wherein
the mounting member includes a first lead, a second lead with one end portion facing one end portion of the first lead, and a molded body made of a resin, the molded body having another end portion of the first lead and another end portion of the second lead embedded therein and protruding in opposite directions, and
the light emitting element bonded to the first lead and the electrostatic discharge protection element bonded to the second lead are provided in the recess of the molded body of the mounting member.

5. The device according to claim 4, further comprising:
a sealing resin layer filled in the recess covering the light emitting element and the translucent resin layer, and being translucent.

6. The device according to claim 5, wherein the sealing resin layer is mixed with phosphor particles capable of absorbing the emitted light from the light emitting element and emitting wavelength-converted light.

7. The device according to claim 4, wherein the electrostatic discharge protection element is a Zener diode connected to the light emitting element in mutually reverse polarity or a varistor.

8. A light emitting device comprising:
a mounting member including a recess;
a light emitting element provided in the recess and made of a semiconductor;
an electrostatic discharge protection element provided in the recess and connected parallel to the light emitting element; and
a translucent resin layer mixed with a filler capable of reflecting emitted light from the light emitting element, covering the electrostatic discharge protection element and not covering the light emitting element,
the recess including a first bottom surface and a second bottom surface, the first bottom surface being bonded to the light emitting element, and the second bottom surface being provided below the first bottom surface bonded to the electrostatic discharge protection element.

9. The device according to claim 8, wherein the electrostatic discharge protection element has an upper surface located below the first bottom surface.

10. The device according to claim 8, further comprising:
a sealing resin layer filled in the recess covering the light emitting element and the translucent resin layer, and being translucent.

11. The device according to claim 10, wherein the sealing resin layer is mixed with phosphor particles capable of absorbing the emitted light from the light emitting element and emitting wavelength-converted light.

12. The device according to claim 8, wherein the mounting member includes a ceramic.

13. The device according to claim 8, wherein the electrostatic discharge protection element is a Zener diode connected to the light emitting element in mutually reverse polarity or a varistor.

14. A light emitting device comprising:
a mounting member including a recess;
a light emitting element provided in the recess and made of a semiconductor;
an electrostatic discharge protection element provided in the recess and connected parallel to the light emitting element; and
a translucent resin layer mixed with a filler capable of reflecting emitted light from the light emitting element, covering the electrostatic discharge protection element and not covering the light emitting element,
the recess including a first bottom surface and a second bottom surface, the first bottom surface being bonded to the light emitting element, and the second bottom surface being provided above the first bottom surface bonded to the electrostatic discharge protection element.

15. The device according to claim 14, wherein the light emitting element has an upper surface located below the second bottom surface.

16. The device according to claim 14, wherein
the recess further includes a sidewall between the first bottom surface and the second bottom surface, and
the sidewall is beveled to make the emitted light from the light emitting element be reflected upward.

17. The device according to claim 14, further comprising:
a sealing resin layer filled in the recess covering the light emitting element and the translucent resin layer, and being translucent.

18. The device according to claim 17, wherein the sealing resin layer is mixed with phosphor particles capable of absorbing the emitted light from the light emitting element and emitting wavelength-converted light.

19. The device according to claim 14, wherein the mounting member includes a ceramic.

20. The device according to claim 14, wherein the electrostatic discharge protection element is a Zener diode connected to the light emitting element in mutually reverse polarity and a varistor.
